(19) United States
(12) Patent Application Publication
(10) Pub. No.: US 2018/0341140 A1
(43) Pub. Date: Nov. 29, 2018

(54) Display Panel, Method For Fabricating The Same And Display Device

(71) Applicants: BOE TECHNOLOGY GROUP CO., LTD., Beijing (CN); HEFEI XINSHENG OPTOELECTRONICS TECHNOLOGY CO., LTD, Hefei, Anhui (CN)

(72) Inventors: Peng LI, Beijing (CN); Yi WANG, Beijing (CN); Yang ZHANG, Beijing (CN)

(73) Assignees: BOE TECHNOLOGY GROUP CO., LTD., Beijing (CN); HEFEI XINSHENG OPTOELECTRONICS TECHNOLOGY CO., LTD., Hefei, Anhui (CN)

(21) Appl. No.: 15/758,878

(22) PCT Filed: Aug. 3, 2017
(86) PCT No.: PCT/CN2017/098621

§ 371 Date: Mar. 9, 2018

(30) Foreign Application Priority Data
Jan. 3, 2017 (CN) 201710002573.1

(51) Int. Cl. G02F 1/1339; G02F 1/1335; G02F 1/1368; H01L 27/12; H01L 21/027; G02F 1/1341

(52) U.S. Cl. CPC G02F 1/13394; G02F 1/133514; G02F 1/1368; H01L 27/1262; G02F 1/13439; H01L 21/0273; G02F 1/1341; G02F 2001/13398; G02F 2001/13396; H01L 27/1288

(57) ABSTRACT

The embodiments of the present disclosure provide a display panel, a method for fabricating the same and a display device. The display panel comprises: a first substrate; a second substrate disposed opposite to the first substrate; and a plurality of pillow spacers disposed between the first substrate and the second substrate and supporting the first substrate and the second substrate, wherein the pillow spacer including a pillow having a first varying height on one side of the first substrate facing the second substrate and a spacer on one side of the second substrate facing the first substrate, the spacer having a second varying height that varies depending on a change of the first varying height such that each pillow spacer has a constant height.

### CROSS-REFERENCE TO RELATED APPLICATION

This application claims priority of China Patent Application No. 201710002573.1, filed on Jan. 3, 2017, the entire content of which is incorporated herein by reference as part of this application.

### TECHNICAL FIELD

The embodiments of the present disclosure relate to a field of display technology, and in particular, to a display panel, a method for fabricating the same and a display device.

### BACKGROUND

Liquid crystal displays (LCDs) are popular among users because of the advantages of space saving, less heat, low power consumption, non-radiation, etc. The components of LCD mainly include a color film substrate, an array substrate, a liquid crystal layer, a polarizer, etc. The liquid crystal layer is formed of liquid crystal disposed between the color filter substrate and the array substrate. The thickness of the liquid crystal layer in LCD greatly affects the light transmittance. When the thickness of the liquid crystal layer is not uniform, light transmitted through the liquid crystal layer may cause display unevenness. Therefore, in order to ensure uniform display of LCD, it is very important to ensure a uniform cell gap.

### SUMMARY OF THE INVENTION

The embodiments of the present disclosure provide a display panel, a method for fabricating the same and a display device. The display panel can improve the uniformity of the cell gap, reduce the probability of display defects, and thereby improve the picture quality and the display effect of the display panel.

In a first aspect of the embodiments of the present disclosure, a display panel is provided. The display panel includes a first substrate, a second substrate disposed opposite to the first substrate, and a plurality of pillow spacers disposed between the first substrate and the second substrate and supporting the first substrate and the second substrate. The pillow spacer includes a pillow having a first varying height on one side of the first substrate facing the second substrate and a spacer on one side of the second substrate facing the first substrate. The spacer has a second varying height that varies depending on a change of the first varying height such that each pillow spacer has a constant height.

In an embodiment of the present disclosure, the first substrate is an array substrate, and the second substrate is a color filter substrate.

In an embodiment of the present disclosure, the pillow includes a gate layer disposed on a surface of the first substrate facing the second substrate.

In an embodiment of the present disclosure, the pillow further includes a gate insulating layer, an active layer, a source/drain electrode layer and a protective layer sequentially disposed on the gate layer.

In an embodiment of the present disclosure, the material of the spacer includes a high-molecular polymer.

In an embodiment of the present disclosure, the display panel further includes a liquid crystal located in a space formed by the pillow spacer, the first substrate and the second substrate.

In a second aspect of the embodiments of the present disclosure, a display device is provided. The display device includes the display panel described in the first aspect of the embodiments of the present disclosure.

In a third aspect of the embodiments of the present disclosure, a method of fabricating a display panel is provided. The method includes: providing a first substrate and a second substrate; forming a pillow having a first varying height on one side of the first substrate facing the second substrate; forming a spacer corresponding to the pillow on one side of the second substrate facing the first substrate, wherein the spacer having a second varying height that varies depending on a change of the first varying height so that a total height of the pillow and the corresponding spacer is constant; and joining the first substrate and the second substrate to form a cell such that each pillow is bonded to the corresponding spacer to form a pillow spacer.

In an embodiment of the present disclosure, forming a spacer corresponding to the pillow on one side of the second substrate facing the first substrate includes: forming a photoresist layer on the second substrate; and patterning the photoresist layer by using a gray tone mask, wherein a light transmission amount of a light-transmitting region of the gray tone mask depends on the first varying height.

In an embodiment of the present disclosure, the method of forming the photoresist layer includes a pigment dispersion method or an inkjet method.

In an embodiment of the present disclosure, the method further includes: before the joining, forming a liquid crystal on one side of the first substrate facing the second substrate or on one side of the second substrate facing the first substrate, or after the joining, introducing a liquid crystal between the first substrate and the second substrate, such that the liquid crystal is located in a space formed by the pillow spacer, the first substrate and the second substrate.

In an embodiment of the present disclosure, a display panel with a pillow spacer having a constant height is provided, which being capable of keeping the distance between the first substrate and the second substrate constant such that the thickness of the liquid crystal located in the space formed by the pillow spacer, the first substrate and the second substrate is constant.

### BRIEF DESCRIPTION OF THE DRAWINGS

FIG. 1 is a schematic view of the cross-section of a display panel according to an embodiment of the present disclosure;

FIG. 2 is a schematic view of the cross-section of a display panel according to an embodiment of the present disclosure;

FIG. 3 is a schematic view of the structure of a display device according to an embodiment of the present disclosure; and

FIG. 4 is a flowchart of a method for fabricating a display panel according to an embodiment of the present disclosure.

### DETAILED DESCRIPTION OF THE INVENTION

The technical solutions in the embodiments of the present disclosure are clearly and completely described below with reference to the accompanying drawings in the embodiments of the present disclosure. Apparently, the described embodiments are merely a part the embodiments of the present disclosure but not all of the embodiments of the present disclosure. All other embodiments obtained by those of ordinary skill in the art based on the embodiments of the present disclosure without any creative efforts shall fall within the protection scope of the present disclosure.

In a process of fabricating the array substrate of the liquid crystal display, the metal film layer of the array substrate is formed by magnetron sputtering. At present, the targets used in the magnetron sputtering process are spliced strip targets. There is a difference in the film forming quality and film forming rate between the central position and the spliced position of the target. The metal film at the center of the target is thick and the metal film at the spliced position of the target is thin. Therefore, a periodic distribution of a thin metal film to a thick metal film will be formed in a direction perpendicular to the target.

In order to maintain the stability and uniformity of the cell gap, a pillow spacer is disposed between the array substrate and the color filter substrate. The pillow spacer includes a spacer and a pillow including a metal film layer of the array substrate. Since the thickness of the metal film layer of the array substrate is periodically distributed, the thickness of the pillow is periodically distributed. After joining the array substrate and the color filter substrate, a periodic distribution of the cell gap will be obtained. In other words, the thickness of the target at the center position is large, and the thickness of the target at the spliced position is small. This makes the light transmittance of the liquid crystal display at the central position of the target greater than the light transmittance at the spliced position of the target, thus resulting in display defects.

The embodiments of the present disclosure provide a display panel, a method for fabricating the same and a display device. The display panel can improve the uniformity of the cell gap, reduce the probability of display defects, and thereby improve the picture quality and the display effect of the display panel.

The exemplary embodiments will now be described more fully with reference to the accompanying drawings.

FIG. 1 is a schematic view of the cross-section of a display panel according to an embodiment of the present disclosure. As shown in FIG. 1, the display panel 1 includes a first substrate 10, a second substrate 20 disposed opposite to the first substrate 10, and a plurality of pillow spacers 40 disposed between the first substrate 10 and the second substrate 20 and supporting the first substrate 10 and the second substrate 20. The pillow spacer 40 includes a pillow 41 having a first varying height on one side of the first substrate 10 facing the second substrate 20 and a spacer 42 on one side of the second substrate 20 facing the first substrate 10. The spacer 42 has a second varying height that varies depending on a change of the first varying height such that each pillow spacer has a constant height.

In addition, in an embodiment of the present disclosure, the display panel 1 may further include a liquid crystal 30 located in a space formed by the pillow spacer 40, the first substrate 10 and the second substrate 20.

In an embodiment of the present disclosure, the first substrate 10 is an array substrate, and the second substrate 20 is a color filter substrate.

In an embodiment of the present disclosure, a plurality of pillow spacers 40 are distributed between the first substrate 10 and the second substrate 20. Each pillow spacer 40 supports the first substrate 10 and the second substrate 20. And the height of each pillow spacer 40 is equal. In each pillow spacer 40, the second varying height of the spacer 42 is related to the first varying height of the pillow 41 and varies depending on a change of the first varying height of the pillow 41, such that the total height of the pillow 41 and the spacer 42 is constant. In other words, a distance between the first substrate 10 and the second substrate 20 is constant, so that the thickness of the liquid crystal 30 introduced (for example, poured) between the first substrate 10 and the second substrate 20 is also constant. Thus, the uniformity of the cell gap is improved so that the light transmittance of the entire display panel 1 is uniform. Thereby, the probability of display defects is reduced, the impact on the display effect is further reduced, and the picture quality and the display effect are improved.

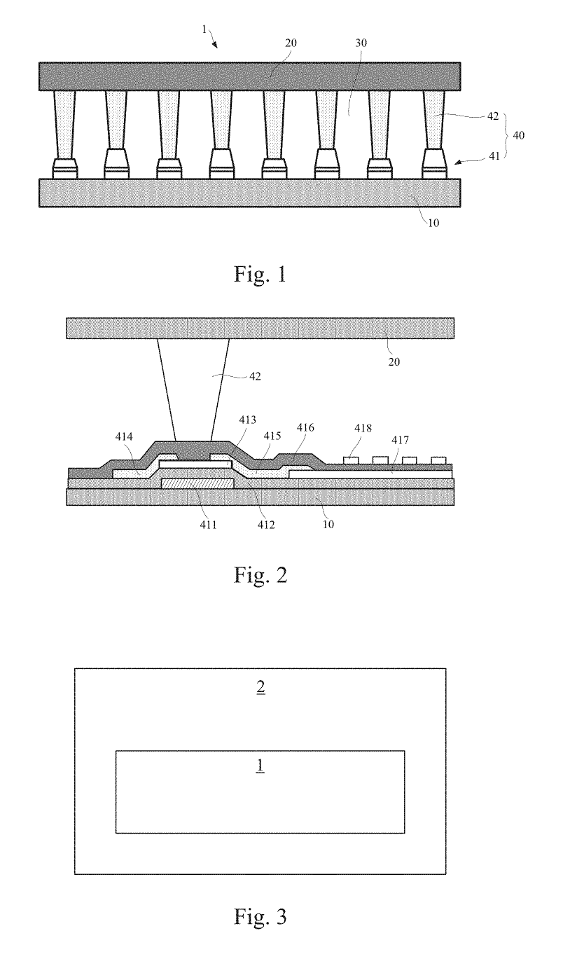

FIG. 2 is a schematic view of the cross-section of a display panel according to an embodiment of the present disclosure. As shown in FIG. 2, the pillow 41 includes a gate layer 411 disposed on a surface of the first substrate 10 facing the second substrate 20. As a result, the spacer 42 is supported between the second substrate 20 and the gate layer 411.

Further, as shown in FIG. 2, the pillow 41 may further include a gate insulating layer 412, an active layer 413, a source/drain electrode layer and a protective layer 416 sequentially disposed on the gate layer 411. In FIG. 2, the source/drain electrode layer may include a source electrode layer 414 and a drain electrode layer 415 disposed between the gate insulating layer 412 and the protective layer 416. At this time, the pillow 41 is formed of the gate layer 411, the gate insulating layer 412, the active layer 413, the source electrode layer 414 and the drain electrode layer 415, and the protective layer 416 so that the spacer 42 is in contact with the protective layer 416.

In an embodiment of the present disclosure, the material of the spacer 42 may be a high-molecular polymer.

The embodiments of the present disclosure further provide a display device. FIG. 3 is a schematic view of the structure of a display device according to an embodiment of the present disclosure. As shown in FIG. 3, the display device 2 includes the display panel 1.

In an embodiment of the present disclosure, the display device 2 may be a thin film transistor-liquid crystal display (TFT-LCD).

In the embodiments of the present disclosure, a method for fabricating a display panel is provided, which is capable of fabricating a display panel with a uniform cell gap and thereby improving the display effect of the display panel.

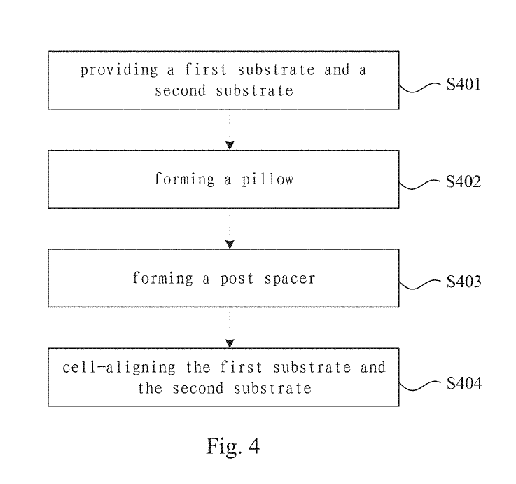

FIG. 4 is a flowchart of a method for fabricating a display panel according to an embodiment of the present disclosure. As shown in FIG. 4, in step S401, the first substrate 10 and the second substrate 20 are provided. In step S402, a pillow is formed. Specifically, a pillow 41 having a first varying height is formed on one side of the first substrate 10 facing the second substrate 20. In step S403, a spacer is formed. Specifically, a spacer 42 corresponding to the pillow 41 is formed on one side of the second substrate 20 facing the first substrate 10. The spacer 42 has a second varying height that varies depending on a change of the first varying height so that the total height of the pillow 41 and the corresponding spacer 42 is constant. In step S404, the first substrate 10 and the second substrate 20 are joined to form a cell such that each pillow 41 is bonded to the corresponding spacer 42 to form a pillow spacer 40.

In addition, the method for fabricating the display panel 1 described above further includes: before the joining, forming a liquid crystal 30 on one side of the first substrate 10 facing the second substrate 20 or on one side of the second substrate 20 facing the first substrate 10, or after the joining, introducing the liquid crystal 30 between the first substrate 10 and the second substrate 20, such that the liquid crystal 30 is located in a space formed by the pillow spacer 40, the first substrate 10, and the second substrate 20.

When the display panel 1 is fabricated by the above fabricating method, by controlling the second varying height of the spacer 42 on the second substrate 20, the second varying height of the spacer 42 varies depending on the change of the first varying height of the corresponding pillow 41, such that the total height of each pillow 41 and the corresponding spacer 42 is constant and thus the distance between the first substrate 10 and the second substrate 20 is constant. Therefore, the thickness of the liquid crystal 30 can be kept uniform and the uniformity of the cell gap can be ensured. Thus, the probability of display defects of the display panel 1 occurred can be reduced, thereby the picture quality and the display effect of the display panel can be improved.

In the display panel 1 fabricated by the above fabricating method, as shown in FIG. 2, a first transparent electrode layer 417 and a second transparent electrode layer 418 are further formed on one side of the first substrate 10 facing the second substrate 20. The first transparent electrode layer 417 and the second transparent electrode layer 418 may be formed of indium tin oxide (ITO), but are not limited to the above materials.

In an embodiment of the present disclosure, forming a spacer corresponding to the pillow 41 on one side of the second substrate 20 facing the first substrate 10 includes: forming a photoresist layer on the second substrate 20; and patterning the photoresist layer by using a gray tone mask to form the spacer 42 having the second varying height with respect to the first varying height of the pillow 41. In addition, the light transmission amount of the light-transmitting region of the gray tone mask depends on the first varying height of the pillow 41. That is, during the formation of the spacer 42 by patterning the photoresist layer by the gray tone mask, the height of the spacer 42 may be controlled by controlling the light transmission amount of the gray tone mask, such that the height of the pillow spacer 40 including the pillow 41 and the spacer 42 is kept constant, so as to ensure the uniformity of the cell gap.

In an embodiment of the present disclosure, the method of forming the photoresist layer includes a pigment dispersion method or an inkjet method.

In an embodiment of the present disclosure, as shown in FIG. 2, the step of forming the pillow 41 may include forming a gate layer 411 on one side of the first substrate 10 facing the second substrate 20. The pillow 41 may include a gate layer 411. In addition, the step of forming the pillow 41 may further include sequentially forming a gate insulating layer 412, an active layer 413, a source/drain electrode layer and a protective layer 416 on the surface of the gate layer 411 and the first substrate 10 facing the second substrate 20. The source/drain electrode layer may include a source electrode layer 414 and a drain electrode layer 415 disposed between the gate insulating layer 412 and the protective layer 416.

Obviously, those skilled in the art may make various alterations and modifications to the present invention without departing from the spirit and scope of the present invention. Therefore, if the alterations and modifications belong to the scope of the claims of the present invention and its equivalent technologies, the present invention intends to include such alterations and modifications.

1. A display panel comprising:
a first substrate;
a second substrate disposed opposite to the first substrate; and
a plurality of pillow spacers disposed between the first substrate and the second substrate and supporting the first substrate and the second substrate, wherein the pillow spacer including a pillow having a first varying height on one side of the first substrate facing the second substrate and a spacer on one side of the second substrate facing the first substrate, the spacer having a second varying height that varies depending on a change of the first varying height such that each pillow spacer has a constant height.

2. The display panel according to claim 1, wherein the first substrate is an array substrate and the second substrate is a color filter substrate.

3. The display panel according to claim 2, wherein the pillow includes a gate layer disposed on a surface of the first substrate facing the second substrate.

4. The display panel according to claim 3, wherein the pillow further comprises a gate insulating layer, an active layer, a source/drain electrode layer and a protective layer sequentially disposed on the gate layer.

5. The display panel according to claim 1, wherein a material of the spacer includes a high-molecular polymer.

6. The display panel according to claim 1, further comprising a liquid crystal located in a space formed by the pillow spacer, the first substrate and the second substrate.

7. A display device comprising the display panel according to claim 1.

8. A method of fabricating a display panel, comprising:
providing a first substrate and a second substrate;
forming a pillow having a first varying height on one side of the first substrate facing the second substrate;
forming a spacer corresponding to the pillow on one side of the second substrate facing the first substrate, the spacer having a second varying height that varies depending on a change of the first varying height so that a total height of the pillow and the corresponding spacer is constant; and
joining the first substrate and the second substrate to form a cell such that each pillow is bonded to the corresponding spacer to form a pillow spacer.

9. The method according to claim 8, wherein forming a spacer corresponding to the pillow on one side of the second substrate facing the first substrate includes: forming a photoresist layer on the second substrate; and patterning the photoresist layer by using a gray tone mask, wherein a light transmission amount of a light-transmitting region of the gray tone mask depends on the first varying height.

10. The method according to claim 9, wherein the method of forming the photoresist layer includes a pigment dispersion method or an inkjet method.

11. The method according to claim 8, further comprising: before the joining, forming a liquid crystal on one side of the first substrate facing the second substrate or on one side of the second substrate facing the first substrate, or after the joining, introducing a liquid crystal between the first substrate and the second substrate, such that the liquid crystal is located in a space formed by the pillow spacer, the first substrate and the second substrate.

12. The display panel according to claim 2, wherein a material of the spacer includes a high-molecular polymer.

13. The display panel according to claim 3, wherein a material of the spacer includes a high-molecular polymer.

14. The display panel according to claim 4, wherein a material of the spacer includes a high-molecular polymer.
